(19) United States
(12) Patent Application Publication
(10) Pub. No.: US 2022/0407393 A1
(43) Pub. Date: Dec. 22, 2022

(54) INSPECTION DEVICE FOR ROTATING ELECTRIC MACHINE, ROTATING ELECTRIC MACHINE, AND METHOD OF INSPECTING ROTATING ELECTRIC MACHINE

(71) Applicant: Mitsubishi Electric Corporation, Tokyo (JP)

(72) Inventors: Norihiko HANA, Tokyo (JP); Masao AKIYOSHI, Tokyo (JP); Hiroshi ARAKI, Tokyo (JP); Daichi GOTO, Tokyo (JP); Kazuaki OGURA, Tokyo (JP)

(73) Assignee: Mitsubishi Electric Corporation, Tokyo (JP)

(21) Appl. No.: 17/774,855

(22) PCT Filed: Dec. 13, 2019
(86) PCT No.: PCT/JP2019/048947

§ 371 Date: May 6, 2022

(51) Int. Cl. H02K 11/20; G01L 1/24; G01R 31/34; G06T 7/00

(52) U.S. Cl. CPC H02K 11/20; G01L 1/24; G01R 31/346; G06T 7/001; G06T 2207/30164

(57) ABSTRACT

Provided is an inspection device for a rotating electric machine, the inspection device including a photographing device, a drive mechanism, a display, and a controller. The photographing device photographs a pattern formed on a surface of a wedge constituting part of an armature. The drive mechanism moves the photographing device with respect to a stator functioning as the armature. The controller detects strain of the wedge by comparing image data of the pattern photographed by the photographing device with reference data of the pattern. In this manner, the inspection device for a rotating electric machine can easily detect the strain of the wedge. Further, the controller estimates loosening of the wedge based on the strain of the wedge, and informs an operator of the rotating electric machine through the display that the loosening of the wedge has occurred.

### TECHNICAL FIELD

This invention relates to an inspection device for a rotating electric machine, a rotating electric machine, and a method of inspecting a rotating electric machine.

### BACKGROUND ART

When a related-art method of measuring a compression amount of an armature coil is used, a change in compression amount of a corrugated leaf spring provided in a slot of a stator core with elapse of time is obtained by measuring a natural frequency of a wedge provided in an opening of the slot of the stator core. When vibration is applied to the wedge with use of an impactor under a state in which a vibration sensor is mounted to the wedge, the natural frequency of the wedge is detected by the vibration sensor (see, for example, Patent Literature 1).

### CITATION LIST

### Patent Literature

[PTL 1] JP 03-82352 A

### SUMMARY OF INVENTION

### Technical Problem

The method as disclosed in Patent Literature 1 has a problem in that time and effort are required to mount the vibration sensor to the wedge and bring the impactor into contact with the wedge so as to measure the natural frequency of the wedge.

This invention has been made to solve the problem described above, and has an object to provide an inspection device for a rotating electric machine, a rotating electric machine, and a method of inspecting a rotating electric machine, which enable easy detection of a state of a wedge constituting part of an armature.

### Solution to Problem

According to one embodiment of this invention, there is provided an inspection device for a rotating electric machine, including: a photographing device configured to photograph a pattern formed on a surface of a wedge constituting part of an armature; and a controller configured to detect strain of the wedge by comparing image data of the pattern photographed by the photographing device with reference data of the pattern.

According to one embodiment of this invention, there is provided an inspection device for a rotating electric machine, including a controller configured to detect strain of a wedge constituting part of an armature by comparing image data of a pattern formed on a surface of the wedge, which has been acquired by a photographing device configured to photograph the pattern, with reference data of the pattern.

According to one embodiment of this invention, there is provided a method of inspecting a rotating electric machine, the method including: a setting step of forming a pattern on a surface of a wedge constituting part of an armature; a photographing step of photographing the pattern with a photographing device; and a detection step of detecting strain of the wedge by comparing image data of the pattern photographed by the photographing device with reference data of the pattern.

According to one embodiment of this invention, there is provided a method of inspecting a rotating electric machine, the method including: a mounting step of mounting a wedge having a surface with a pattern into an armature; a photographing step of photographing the pattern with a photographing device; and a detection step of detecting strain of the wedge by comparing image data of the pattern photographed by the photographing device with reference data of the pattern.

### Advantageous Effects of Invention

The inspection device for a rotating electric machine, the rotating electric machine, and the method of inspecting a rotating electric machine according to one embodiment of this invention enable easy detection of a state of the wedge constituting part of the armature.

### BRIEF DESCRIPTION OF DRAWINGS

FIG. 1 is a schematic sectional view of an inspection device for a rotating electric machine and a rotating electric machine according to a first embodiment, and includes a block illustration of part of the inspection device for a rotating electric machine.

FIG. 2 is a front view of a stator and a rotor of FIG. 1 when viewed in an axial direction.

FIG. 3 is a view of part of an inner peripheral portion of the stator of FIG. 1 when viewed from the rotor side.

FIG. 4 is a sectional view of a main part of the stator of FIG. 1.

FIG. 5 is a perspective view for illustrating a structure inside a stator core slot of FIG. 4.

FIG. 6 is a plan view of a wedge of FIG. 4.

FIG. 7 is a front view of the wedge of FIG. 6.

FIG. 8 is a block diagram of the inspection device for a rotating electric machine of FIG. 1.

FIG. 9 is a flowchart for illustrating a wedge loosening inspection routine to be executed by the inspection device for a rotating electric machine of FIG. 8.

FIG. 10 is a flowchart for illustrating a sub-routine of strain analysis processing in FIG. 9.

FIG. 11 is a plan view for illustrating a wedge of a rotating electric machine according to a second embodiment.

FIG. 12 is a plan view for illustrating a wedge of a rotating electric machine according to a third embodiment.

FIG. 13 is a plan view for illustrating a wedge of a rotating electric machine according to a fourth embodiment.

FIG. 14 is a plan view for illustrating a wedge of a rotating electric machine according to a fifth embodiment.

FIG. 15 is a plan view for illustrating a wedge of a rotating electric machine according to a sixth embodiment.

FIG. 16 is a plan view for illustrating a wedge of a rotating electric machine according to a seventh embodiment.

FIG. 17 is a plan view for illustrating a wedge of a rotating electric machine according to an eighth embodiment.

FIG. 18 is a view of part of an inner peripheral portion of a stator of a rotating electric machine according to a ninth embodiment when viewed from a rotor side.

FIG. 19 is a plan view for illustrating a wedge of a rotating electric machine according to a tenth embodiment.

FIG. 20 is a view for illustrating a positional relationship between a photographing device of a rotating electric machine according to an eleventh embodiment and a wedge.

FIG. 21 is a configuration diagram for illustrating a first example of a processing circuit for implementing functions of the inspection devices for a rotating electric machine according to the first embodiment to the eleventh embodiment.

FIG. 22 is a configuration diagram for illustrating a second example of the processing circuit for implementing the functions of the inspection devices for a rotating electric machine according to the first embodiment to the eleventh embodiment.

### DESCRIPTION OF EMBODIMENTS

Now, embodiments are described with reference to the drawings.

### First Embodiment

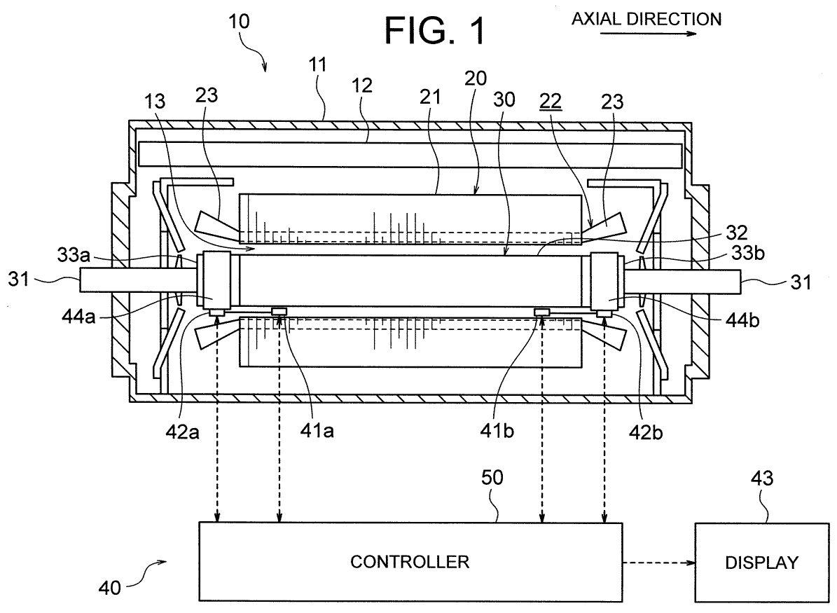

FIG. 1 is a schematic sectional view of an inspection device for a rotating electric machine and a rotating electric machine being a target to be inspected according to a first embodiment, and includes a block illustration of part of the inspection device for a rotating electric machine. The rotating electric machine according to the first embodiment is a turbine generator that obtains a rotational force from a turbine functioning as a motor.

As illustrated in FIG. 1, a rotating electric machine 10 includes a frame 11, a gas cooler 12, a stator 20, and a rotor 30. The stator 20 is an armature, and the rotor 30 is a field system. The gas cooler 12, the stator 20, and the rotor 30 are accommodated in the frame 11.

Refrigerant for removing heat generated by power generation circulates inside the frame 11. As the refrigerant, for example, a cooling gas is used. The gas cooler 12 cools the circulating refrigerant.

The stator 20 includes a stator core 21 having a cylindrical shape and a stator winding 22. The stator core 21 is fixed inside the frame 11. The stator winding 22 is fixed to an inner peripheral portion of the stator core 21.

Both ends of the stator winding 22 in an axial direction of the stator core 21 project from the stator core 21, and form coil ends 23, respectively. A main lead (not shown) is connected to one of the coil ends 23. The main lead is drawn out to an outside of the frame 11. Power generated by the rotating electric machine 10 is extracted to the outside through the main lead.

The axial direction of the stator core 21 is a direction along an axial center of the stator core 21, and corresponds to a right-and-left direction of FIG. 1. A radial direction of the stator core 21 is a radial direction of a circle having the axial center of the stator core 21 as a center. A circumferential direction of the stator core 21 is a direction along a circular arc having the axial center of the stator core 21 as a center.

The rotor 30 includes a pair of rotary shafts 31, a rotor core 32, a first retaining ring 33a, and a second retaining ring 33b. The pair of rotary shafts 31 project outward in an axial direction of the rotor core 32 from both ends of the rotor core 32 in its axial direction. The pair of rotary shafts 31 and the rotor core 32 are arranged coaxially with the stator core 21.

The axial direction of the rotor core 32 is a direction along an axial center of the rotor core 32, and corresponds to the right-and-left direction of FIG. 1. A radial direction of the rotor core 32 is a radial direction of a circle having the axial center of the rotor core 32 as a center. A circumferential direction of the rotor core 32 is a direction along a circular arc having the axial center of the rotor core 32 as a center.

A pair of bearings (not shown) are provided to the frame 11. The pair of rotary shafts 31 are rotatably supported in the frame 11 through intermediation of the pair of bearings. The rotor 30 rotates relative to the stator 20 through transmission of a driving force from the turbine described above. The stator core 21 and the stator winding 22 are located on a radially outer side of the rotor core 32.

A gap 13 is defined by the stator core 21 and the rotor core 32. A field winding (not shown) is fixed to the rotor core 32. A magnetic field generated from the rotor core 32 moves across the stator winding 22 through the rotation of the rotor 30. As a result, an electromotive force is generated in the stator winding 22 to generate a current.

The first retaining ring 33a and the second retaining ring 33b are mounted to both ends of the rotor core 32 in the axial direction to retain the field winding wound around the rotor core 32. The first retaining ring 33a and the second retaining ring 33b are exposed outside the stator core 21.

An inspection device 40 includes a first photographing device 41a, a second photographing device 41b, a first drive mechanism 42a, a second drive mechanism 42b, a display 43, a first guide ring 44a, a second guide ring 44b, and a controller 50.

The first photographing device 41a, the second photographing device 41b, the first drive mechanism 42a, the second drive mechanism 42b, the first guide ring 44a, and the second guide ring 44b are provided inside the frame 11. The display 43 and the controller 50 are provided outside the frame 11, specifically, outside the rotating electric machine 10.

The first photographing device 41a is arranged on one side with respect to a center of the stator core 21 in the axial direction. The second photographing device 41b is arranged on the other side with respect to the center of the stator core in the axial direction. Each of the first photographing device 41a and the second photographing device 41b includes a camera and a light.

The first guide ring 44a is provided around the first retaining ring 33a while being fixed to the frame 11. The second guide ring 44b is provided around the second retaining ring 33b while being fixed to the frame 11. Thus, the first guide ring 44a and the second guide ring 44b do not rotate even when the rotor 30 rotates.

The first drive mechanism 42a is arranged on an outer side of one end of the stator core 21 in the axial direction. Further, the first drive mechanism 42a is guided by the first guide ring 44a to be movable in the circumferential direction of the stator core 21.

The second drive mechanism 42b is arranged on an outer side of the other end of the stator core 21 in the axial direction. Further, the second drive mechanism 42b is guided by the second guide ring 44b to be movable in the circumferential direction of the stator core 21.

The first drive mechanism 42a has a first arm that is expandable and contractable. The first photographing device 41a is supported by the first arm, and is movable in the axial direction of the stator core 21 through expansion and contraction of the first arm. Similarly, the second drive mechanism 42b has a second arm that is expandable and contractable. The second photographing device 41b is supported by the second arm, and is movable in the axial direction of the stator core 21 through expansion and contraction of the second arm.

The above-mentioned configuration enables the first drive mechanism 42a to move the first photographing device 41a in the axial direction and the circumferential direction of the stator core 21 with respect to the stator 20. The above-mentioned configuration also enables the second drive mechanism 42b to move the second photographing device 41b in the axial direction and the circumferential direction of the stator core 21 with respect to the stator 20.

FIG. 1 is an illustration of a state when the rotating electric machine 10 is inspected by the inspection device 40. In this state, the first photographing device 41a and the second photographing device 41b are inserted into and located in the gap 13. When the rotating electric machine 10 operates, the first photographing device 41a and the second photographing device 41b are led out from the gap 13, specifically, are retreated to an outside of the stator core 21.

The controller 50 is connected to the first photographing device 41a, the second photographing device 41b, the first drive mechanism 42a, the second drive mechanism 42b, and the display 43. Any of wired connection and wireless connection may be used as a connection method for the above-mentioned components. The controller 50 controls the first photographing device 41a, the second photographing device 41b, the first drive mechanism 42a, the second drive mechanism 42b, and the display 43.

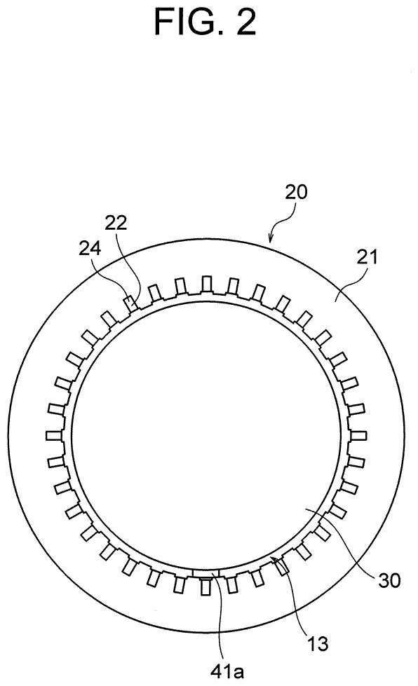

FIG. 2 is a front view of the stator 20 and the rotor 30 of FIG. 1 when viewed in the axial direction. The inner peripheral portion of the stator core 21 has a plurality of stator core slots 24. Each of the stator core slots 24 is a groove extending in the axial direction of the stator core 21. Further, the plurality of stator core slots 24 are formed at equal intervals in the circumferential direction of the stator core 21. The stator winding 22 is inserted into those stator core slots 24.

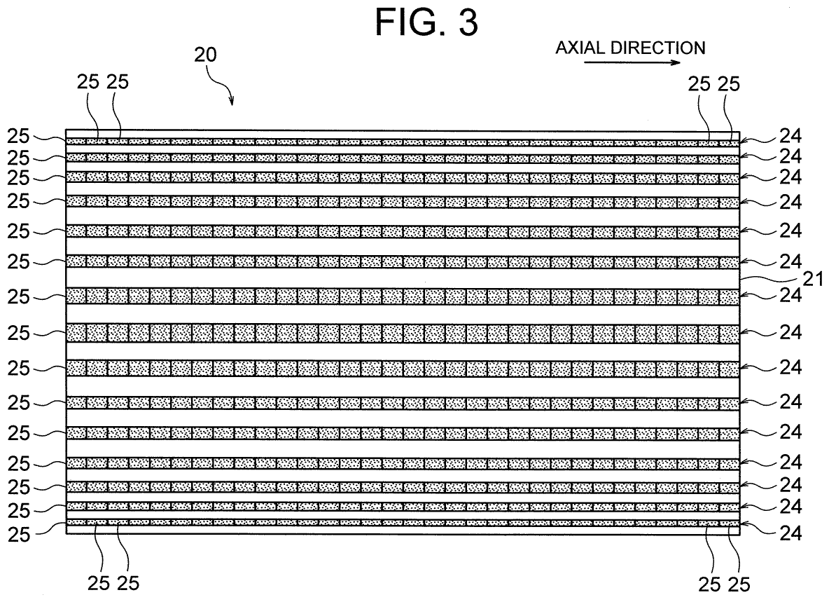

FIG. 3 is a view of part of an inner peripheral surface of the stator core 21 when viewed from the rotor side. A plurality of wedges 25 are mounted in each of the stator core slots 24. The plurality of wedges 25 are arranged in the axial direction of the stator core 21. Further, the plurality of wedges 25 prevent the stator winding 22 from coming out of the stator core slots 24.

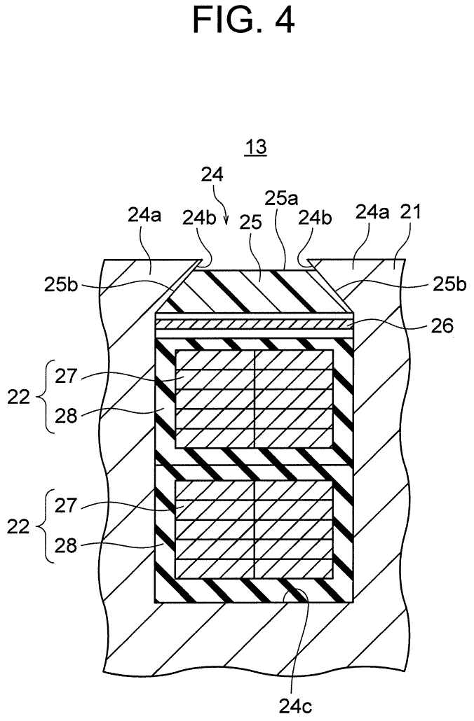

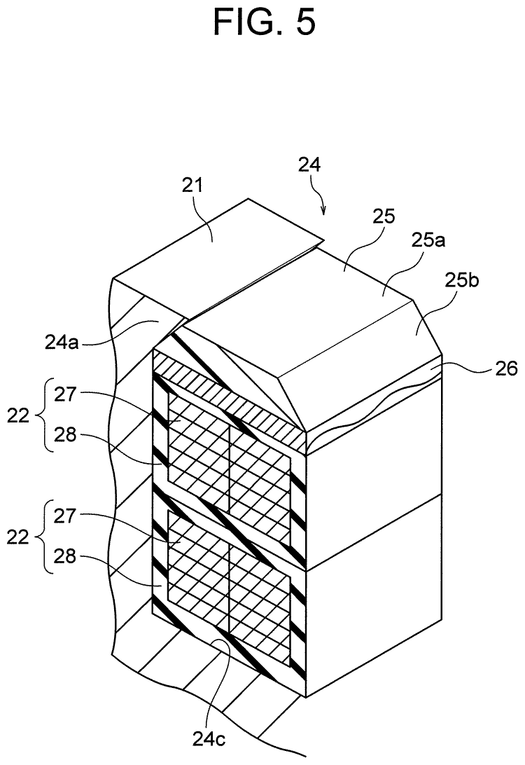

FIG. 4 is a sectional view of a main part of the stator of FIG. 1, and is an illustration of a cross section of one stator core slot 24 in an enlarged manner. FIG. 5 is a perspective view for illustrating a structure inside the stator core slot 24 of FIG. 4.

Right and left walls of each of the stator core slots 24 have a pair of protruding portions 24a. The pair of protruding portions 24a are located at a radially inner end of the stator core 21. Further, the pair of protruding portions 24a protrude and face each other in the circumferential direction of the stator core 21 in such a manner that an opening width of a corresponding one of the stator core slots 24 is narrowed.

The pair of protruding portions 24a have slopes 24b that are bilaterally symmetrical. A width of a part of the stator core slot 24, which is located between the pair of protruding portions 24a, gradually decreases in a radially inward direction of the stator core 21.

The stator winding 22, the plurality of wedges 25, and a plurality of springs 26 are accommodated in each of the stator core slots 24. As described above, the stator 20 includes, in addition to the stator core 21 and the stator winding 22, the plurality of wedges 25 and the plurality of springs 26. Specifically, each of the wedges 25 constitutes part of the stator 20. The stator winding 22 includes a plurality of conductors 27 and a plurality of insulations 28 made of a resin.

A sectional shape of the wedge 25, which is taken along a plane perpendicular to the axial direction of the stator core 21, is a bilaterally symmetrical trapezoid under a state in which the wedge 25 is mounted in the stator core slot 24. Fiber reinforced plastic is used as a material of the wedges 25.

A surface of the wedge 25 includes an exposed surface 25a being a target surface to be inspected and a pair of tapered surfaces 25b. The exposed surface 25a is part of the surface of the wedge 25, which is located on a radially inner side of the stator core 21 and on a side opposite to a surface on the stator winding 22 side. The exposed surface 25a is exposed in the gap 13. The pair of tapered surfaces 25b is a pair of slopes being part of the surface of the wedge 25, which is located on the right and the left of the exposed surface 25a, and is continuous with the exposed surface 25a. The pair of tapered surfaces 25b are in contact with the slopes 24b that are bilaterally symmetrical, and are not exposed in the gap 13.

Each of the springs 26 is a corrugated leaf spring that is corrugated in the axial direction of the stator core 21. The spring 26 is not in contact with the stator winding 22 or the wedge 25 in the cross section illustrated in FIG. 4. In practice, however, the spring 26 is sandwiched between the wedge 25 corresponding to the spring 26 and the stator winding 22, and is compressed in the radial direction of the stator core 21. A length of each of the springs 26 in the axial direction of the stator core 21 is equal to a length of each of the wedges 25 in the axial direction.

Each of the springs 26 presses the stator winding 22 against a bottom surface 24c of the stator core slot 24, and presses the pair of tapered surfaces 25b of corresponding one of the wedges 25 against the pair of slopes 24b.

Incidentally, as described above, when the rotor 30 rotates, a current flows through the stator winding 22. When a current flows through the stator winding 22, an electromagnetic excitation force is generated in the stator winding 22. The electromagnetic excitation force is a force to vibrate the stator winding 22. However, when a force to press the stator winding 22 against the bottom surface 24c is larger than the electromagnetic excitation force, the vibration of the stator winding 22 is suppressed.

Each of the wedges 25 is constrained in the stator core slot 24 only by the pair of tapered surfaces 25b. Thus, a central portion of each of the wedges 25 in the circumferential direction of the stator core 21 may deform in a projecting manner toward a radially inner side of the stator core 21 with elapse of time. In other words, the exposed surface 25a of each of the wedges 25 may be stretched mainly in the circumferential direction of the stator core 21 by a force of the spring 26.

When such deformation of the wedge 25 occurs, the force of the spring 26 to press the stator winding 22 against the bottom surface 24c weakens. Further, the deformation of the wedge 25 is quantified as strain of the wedge 25.

As described above, the strain of the wedge 25 and the force of the spring 26 to press the stator winding 22 against the bottom surface 24c have a correlation. The force of the spring 26 to press the stator winding 22 against the bottom surface 24c is hereinafter referred to as “pressing force.” Further, the deformation of the wedge 25, which may reduce the pressing force, is referred to as “loosening” of the wedge 25.

When the loosening of the wedge 25 occurs and the pressing force becomes smaller than the electromagnetic excitation force, the stator winding 22 vibrates inside the stator core slot 24. When the stator winding 22 continues vibrating over a long period of time, the stator winding 22 may be mechanically damaged due to friction against members therearound. Thus, the inspection device 40 detects strain of the wedge 25, and estimates loosening of the wedge 25 based on the detected strain of the wedge 25. Then, the inspection device 40 informs an operator of the occurrence of loosening of the wedge 25 through the display 43.

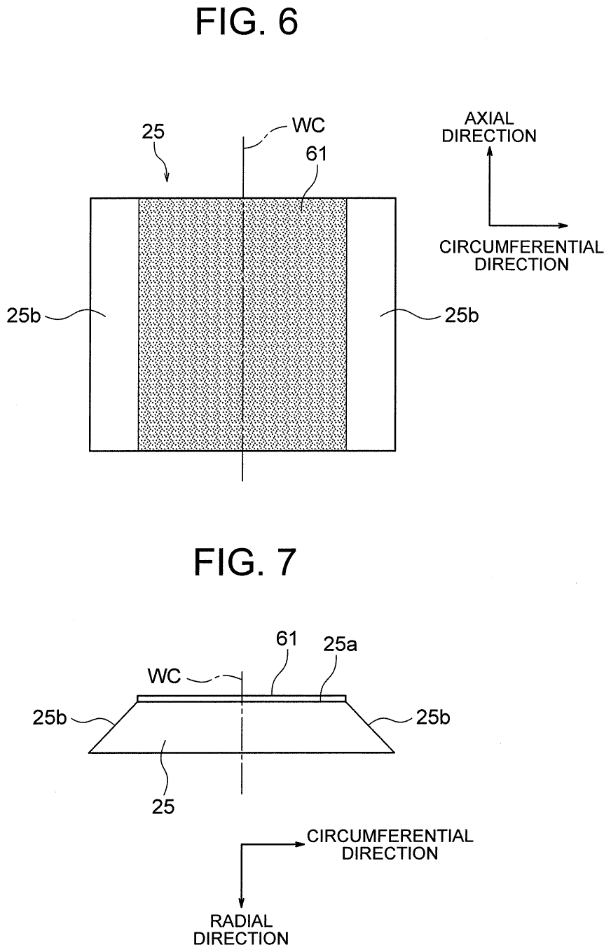

FIG. 6 is a plan view of the wedge 25 of the rotating electric machine 10 according to the first embodiment. Further, FIG. 7 is a front view of the wedge 25 of FIG. 6. Alternate long and short dash lines illustrated in FIG. 6 and FIG. 7 represent a center WC of the wedge 25 in the circumferential direction of the stator core 21. As illustrated in FIG. 6, the exposed surface 25a of the wedge 25 has a random pattern 61, which is formed as a pattern through application.

The random pattern 61 is a pattern without regularity, and has, for example, a plurality of randomly arranged dots. Further, the random pattern 61 is formed by, for example, spraying paint onto the exposed surface 25a of the wedge 25.

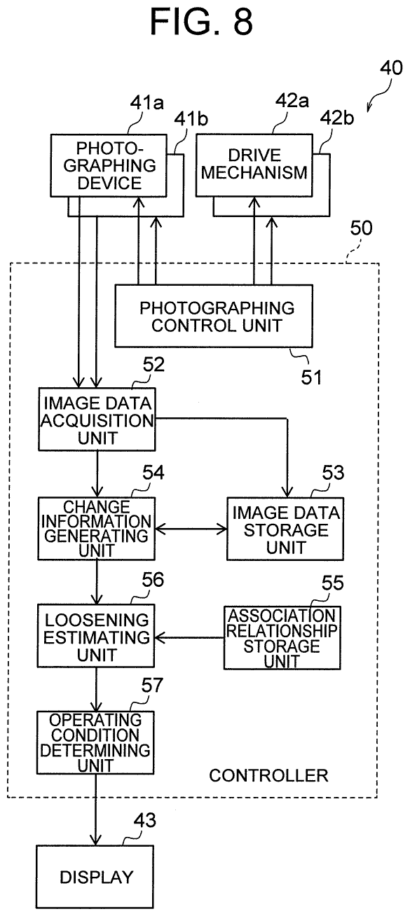

FIG. 8 is a block diagram for illustrating the inspection device 40 of FIG. 1. The controller 50 includes, as functional blocks, a photographing control unit 51, an image data acquisition unit 52, an image data storage unit 53, a change information generating unit 54, an association relationship storage unit 55, a loosening estimating unit 56, and an operating condition determining unit 57.

The photographing control unit 51 uses the first drive mechanism 42a to move the first photographing device 41a, and controls the first photographing device 41a to photograph the exposed surface 25a of the wedge 25, which is a target to be inspected. Specifically, the photographing control unit 51 controls the first photographing device 41a to photograph the random pattern 61 formed on the exposed surface 25a of each of the wedges 25. More specifically, the photographing control unit 51 first moves the first photographing device 41a to a position of the wedge 25 being a target to be inspected. After that, the photographing control unit 51 divides the random pattern 61 formed on the wedge 25 being a target to be inspected into a plurality of regions, and then photographs the plurality of regions in order.

After finishing photographing all of the plurality of regions of the exposed surface 25a of the wedge 25 being a target to be inspected, the photographing control unit 51 moves the first photographing device 41a to a position of the wedge 25 being a next target to be inspected. Then, the photographing control unit 51 divides the random pattern 61 of the wedge 25 being a next target to be inspected into a plurality of regions, and then photographs the plurality of regions in order. In this manner, the random patterns 61 of all the wedges 25 being targets to be inspected are photographed.

Similarly, the photographing control unit 51 uses the second drive mechanism 42b to move the second photographing device 41b, and controls the second photographing device 41b to photograph the exposed surface 25a of one of the wedges 25, which is a target to be inspected.

At each inspection time, the photographing control unit 51 performs the above-mentioned photographing operation. In this case, the “inspection time” refers to an end of a predetermined time period from the last inspection time. The predetermined time period is a fixed time period.

The image data acquisition unit 52 acquires a plurality of pieces of image data of the plurality of random patterns 61 that have been photographed at a current inspection time from the first photographing device 41a and the second photographing device 41b. Further, the image data acquisition unit 52 sends the plurality of acquired pieces of image data to the image data storage unit 53 and the change information generating unit 54.

The image data storage unit 53 stores the plurality of pieces of image data sent from the image data acquisition unit 52.

The change information generating unit 54 compares each of the pieces of image data sent from the image data acquisition unit 52 with a piece of reference data, which corresponds to the piece of image data. The reference data is image data that has been obtained by photographing, at the previous inspection time, the random pattern 61 at the same position as a position at which the sent image data has been obtained. Specifically, the reference data is the image data of the random pattern 61 that has been photographed previously. Each of the pieces of image data stored in the image data storage unit 53 at the current inspection time serves as reference data to be used for comparison at a next inspection time.

The change information generating unit 54 compares each of the pieces of image data photographed at the current inspection time and the reference data corresponding to the image data photographed at the current inspection time to thereby extract a change in shape of the random pattern 61 contained in the image data. Further, the change information generating unit 54 detects strain of the wedge 25 being a target to be inspected based on the extracted change in shape of the random pattern 61. In other words, the controller 50 detects strain of the wedge 25 by comparing each of the pieces of the image data with a piece of the reference data, which corresponds to the piece of image data. Then, the change information generating unit 54 generates a temporal change in the detected strain as strain change information.

The strain is detected by using a publicly known digital image correlation method. The digital image correlation method is a method of photographing a surface of a target object before and after occurrence of deformation of the target object and then simultaneously calculating the amount of displacement and a direction of displacement of the surface of the target object from a luminance distribution of obtained digital image data.

The change information generating unit 54 generates in-plane strain distribution information from results of detection of strain of the plurality of regions of each of the plurality of random patterns 61. Further, the change information generating unit 54 generates temporal change information of the in-plane strain distribution as strain change information.

The association relationship storage unit 55 stores an association relationship between a change in strain and the degree of loosening of the wedge 25. The degree of loosening is the amount corresponding to the amount of decrease in pressing force. More specifically, the association relationship is determined in advance by an actual measurement or simulation, and is stored as a lookup table defining a relationship between a temporal change in in-plane strain distribution and the degree of loosening of the wedge 25.

The loosening estimating unit 56 estimates the degree of loosening of each of the wedges 25 based on the strain change information generated by the change information generating unit 54. More specifically, the loosening estimating unit 56 applies a temporal change in the generated in-plane strain distribution to the lookup table defining the relationship between a temporal change in in-plane strain distribution and the degree of loosening of the wedge 25, which is stored in the association relationship storage unit 55. In this manner, the loosening estimating unit 56 estimates the degree of loosening of each of the wedges 25.

The operating condition determining unit 57 determines appropriate conditions as operating conditions for the rotating electric machine 10 based on the estimated degrees of loosening of the wedges 25, and outputs the determined operating conditions to the display 43. The operating conditions include an appropriate output and an operable time period of the rotating electric machine 10.

The appropriate output is, for example, an output that can suppress the progression of loosening of the wedge 25 in which loosening has occurred. The operable time period is a time period in which the rotating electric machine 10 can continue operating under the determined appropriate output. In this case, the operating condition determining unit 57 calculates the appropriate output and the operable time period of the rotating electric machine 10 based on positional information of the wedge 25 in which loosening has occurred and the degree of loosening of the wedge 25. In this manner, an operator is urged to take appropriate measures before the stator winding 22 is damaged.

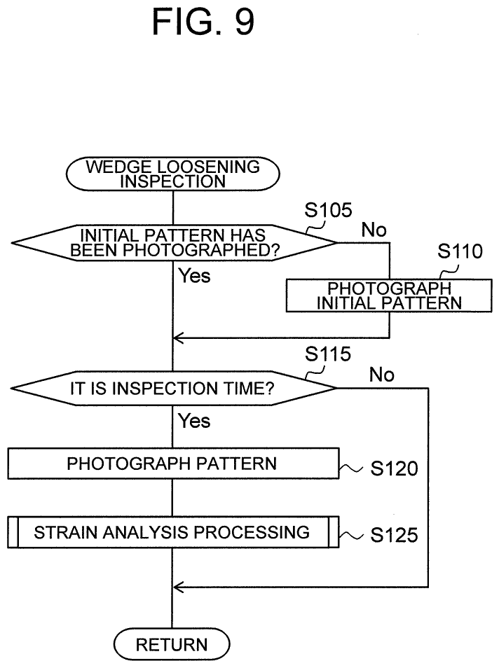

FIG. 9 is a flowchart for illustrating a wedge loosening inspection routine to be executed by the controller 50. The routine of FIG. 9 is set to be started, for example, when the inspection device 40 is started up and to be executed at predetermined time intervals.

After starting the routine of FIG. 9, the controller 50 first determines, in Step S105, whether an initial pattern has been photographed. The initial pattern is, for example, the random pattern 61 that is photographed for the first time after assembly of the rotating electric machine 10 including the inspection device 40. The initial pattern may also be a pattern that is photographed for the first time after the inspection device 40 is newly incorporated into the rotating electric machine 10 or after the wedge 25 mounted into the stator core 21 is replaced with another wedge 25 having the random pattern 61 formed through application.

When the initial pattern has already been photographed, the controller 50 determines, in Step S115, whether it is an inspection time.

Meanwhile, when the initial pattern has not been photographed yet, the controller 50 photographs the initial pattern in Step S110. Then, in Step S115, the controller 50 determines whether it is an inspection time.

When it is not an inspection time yet, the controller 50 terminates this routine in this step.

Meanwhile, when it is already an inspection time, the controller 50 controls, in Step S120, the first photographing device 41a or the second photographing device 41b to photograph the random pattern 61 formed on each of the wedges 25. Next, the controller 50 executes strain analysis processing in Step S125, and then terminates this routine in this step.

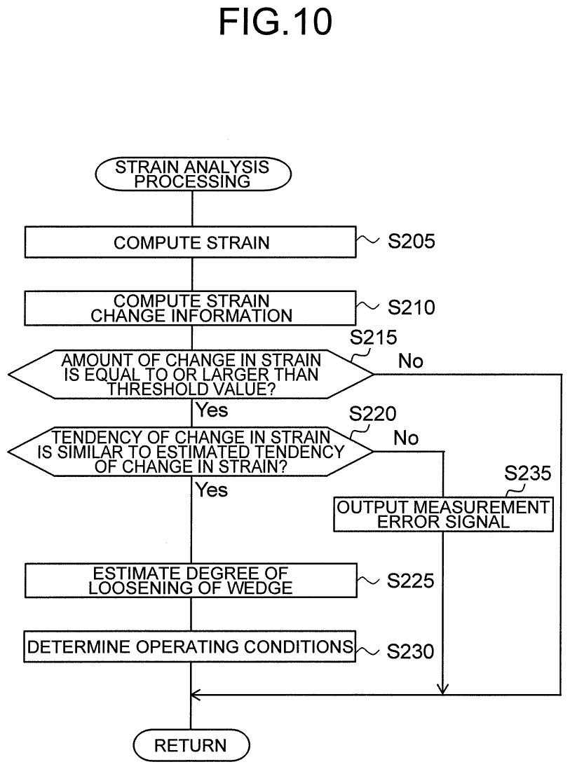

FIG. 10 is a flowchart for illustrating a sub-routine of strain analysis processing in FIG. 9. After starting the routine of FIG. 10, the controller 50 first computes strain of each of the wedges 25 by using the digital image correlation method in Step S205.

Next, in Step S210, the controller 50 computes strain change information. The strain change information is information based on values of strain computed between the routine executed after the start-up of the controller 50 and the currently executed routine. For example, the strain change information contains a shift of the strain from one inspection time to another one. Further, the strain change information contains in-plane distribution information of the strain on the exposed surface 25a of each of the wedges 25 at each inspection time.

Next, in Step S215, the controller 50 determines, based on the computed strain change information, whether the amount of change in strain of each of the wedges 25 is equal to or larger than a threshold value. When the amount of change in strain of each of the wedges 25 is less than the threshold value, the controller 50 terminates this routine in this step.

Meanwhile, in Step S220, the controller 50 determines whether a tendency of change in strain based on the strain change information is similar to an “estimated tendency of change in strain” for the wedge 25 with which the amount of change in strain based on the strain change information is equal to or larger than the threshold value.

The “estimated tendency of change in strain” is obtained in advance by an actual measurement or simulation, and is stored in a storage unit included in the controller 50. Whether the tendency of change in strain based on the strain change information is similar to the “estimated tendency of change in strain” is determined, for example, from the degree of correlation between approximate functions of the changes in strain.

When the tendency of change in strain based on the strain change information is not similar to the “estimated tendency of change in strain,” the controller 50 outputs a measurement error signal in Step S235, and terminates this routine in this step.

A measurement error is an error indicating that strain of the wedge 25 is not precisely measured due to, for example, a failure of the first photographing device 41a, the second photographing device 41b, the first drive mechanism 42a, the second drive mechanism 42b, the controller 50, or other components. Further, the measurement error indicates that, for example, the tendency of change in strain is different from the “estimated tendency of change in strain” although the strain of the wedge 25 has been precisely measured.

Meanwhile, when the tendency of change in strain based on the strain change information is similar to the “estimated tendency of change in strain,” the controller 50 estimates the degree of loosening of each of the wedges 25 in Step S225. The controller 50 performs the process step of Step S225 for all the wedges 25 with which the amount of change in strain based on the strain change information is equal to or larger than the threshold value. Next, in Step S230, the controller 50 determines the operating conditions for the rotating electric machine 10 based on the estimated degrees of loosening of the wedges 25, and outputs the determined operating conditions to the display 43.

As described above, according to the inspection device 40 for a rotating electric machine of the first embodiment, through use of the first photographing device 41a or the second photographing device 41b, the random pattern 61 formed on the exposed surface 25a of each of the wedges 25 constituting part of the stator 20 is photographed. Then, each piece of the image data of the photographed random patterns 61 is compared with a piece of the reference data of the random patterns 61, which corresponds to the piece of the image data. As a result, strain of each of the wedges 25 is detected. Further, the degree of loosening of the wedge 25 is estimated based on the detected strain of the wedge 25.

Thus, the strain as a state of each of the wedges 25 constituting part of the stator 20 is easily detected. Further, the degree of loosening of each of the wedges 25 is easily estimated. As a result, appropriate operating conditions for the rotating electric machine 10 are determined.

Incidentally, when a related-art inspection device that uses an impactor to apply vibration to the wedge so as to measure a natural frequency of the wedge by a vibration sensor is employed, a large number of steps are required to bring the inspection device and the wedges into contact with each other. Thus, when strain of the wedge is inspected, a speed of moving the inspection device inside the rotating electric machine is limited. Meanwhile, according to the inspection device 40 for a rotating electric machine of the first embodiment, the inspection device and the wedges are not required to be brought into contact with each other. Thus, when strain of the wedge is inspected, a speed of moving the inspection device inside the rotating electric machine is not limited. As described above, according to the inspection device 40 for a rotating electric machine of the first embodiment, it is possible to shorten an inspection time period so as to be shorter than an inspection time period required by the related-art inspection device.

Further, the inspection device 40 includes the first drive machine 42a for moving the first photographing device 41a with respect to the stator 20 and the second drive mechanism 42b for moving the second photographing device 41b with respect to the stator 20. The first drive mechanism 42a and the second drive mechanism 42b are controlled by the controller 50. Thus, the strain of the wedge can be detected without disassembling the rotating electric machine 10.

Further, the reference data is image data of the random pattern 61 photographed at the previous inspection time. Specifically, the reference data is the image data of the random pattern 61 that has been previously photographed. Thus, the strain of the wedge 25 in the axial direction and the circumferential direction of the stator core 21 can be detected with higher accuracy by using the digital image correlation method.

The random pattern 61 may be formed on the exposed surface 25a of each of the wedges 25 after the plurality of wedges 25 are mounted in the stator core slots 24. In this case, a method of inspecting a rotating electric machine according to the first embodiment includes a setting step, a photographing step, and a detection step.

In the setting step, the random pattern 61 is formed on the exposed surface 25a of each of the wedges 25 constituting part of the stator 20 functioning as an armature. In the photographing step, the random patterns 61 are photographed by the first photographing device 41a or the second photographing device 41b. In the detection step, the strain of the wedge 25 is detected by comparing each piece of the image data of the random pattern 61 photographed by the first photographing device 41a or the second photographing device 41b with a piece of the reference data of the random pattern 61, which corresponds to the piece of image data.

The above-mentioned method enables formation of the random pattern 61 on the surface of each of the wedges 25 that have already been mounted without removal of the wedges 25 from the stator core 21. Thus, the random patterns 61 can easily be formed.

Further, the plurality of wedges 25, each having the random pattern 61 formed in advance on its exposed surface 25a, may be mounted into the stator core slots 24. In this case, a method of inspecting a rotating electric machine according to the first embodiment includes a mounting step, a photographing step, and a detection step.

In the mounting step, the wedges 25, each having the random pattern 61 on its exposed surface 25a, are mounted into the stator 20. In the photographing step, the random patterns 61 are photographed by the first photographing device 41a or the second photographing device 41b. In the detection step, the strain of the wedge 25 is detected by comparing each piece of the image data of the random pattern 61 photographed by the first photographing device 41a or the second photographing device 41b with a piece of the reference data of the random pattern 61, which corresponds to the piece of image data.

The above-mentioned method enables easy formation of the random patterns 61 when the stator 20 is newly assembled or the wedges 25 are replaced.

The inspection device 40 may be separated from the rotating electric machine 10 onto which the first photographing device 41a and the second photographing device 41b are mounted. In this case, the inspection device 40 may be connected to the first photographing device 41a and the second photographing device 41b at a time of inspection, or one controller 50 may be shared by a plurality of rotating electric machines 10.

### Second Embodiment

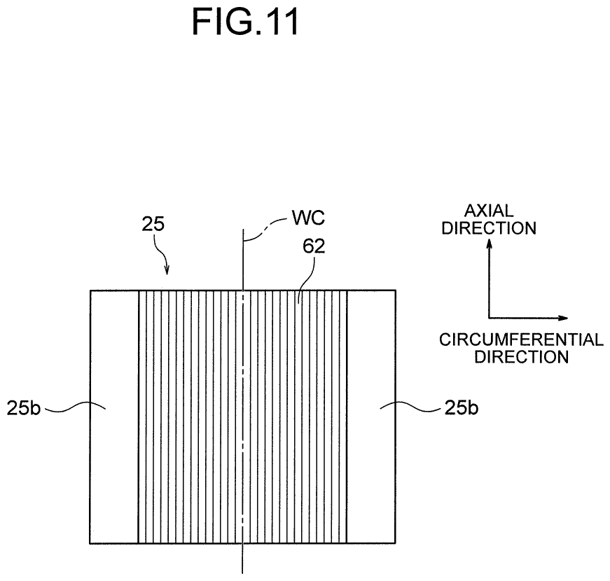

FIG. 11 is a plan view for illustrating a wedge 25 of a rotating electric machine according to a second embodiment. As illustrated in FIG. 11, an exposed surface 25a of the wedge 25 has a stripe pattern 62, which is formed as a pattern through application.

The stripe pattern 62 has a plurality of straight lines arranged in parallel to each other at equal intervals. The stripe pattern 62 is formed on the exposed surface 25a of the wedge 25 through application so that the plurality of straight lines become parallel to an axial direction of a stator core 21.

A configuration of an inspection device 40 for a rotating electric machine 10, a configuration of the rotating electric machine 10, and a method of inspecting the rotating electric machine 10 are the same as those in the first embodiment except that a pattern is the stripe pattern 62.

As described above, a force to stretch the exposed surface 25a of the wedge 25 acts on the exposed surface 25a mainly in a circumferential direction of the stator core 21. Thus, strain of the wedge 25 in the circumferential direction of the stator core 21 has a tendency to become larger than strain of the wedge 25 in the axial direction of the stator core 21. Further, the strain of the wedge 25 in the circumferential direction of the stator core 21 is the largest at a center WC of the wedge 25 in the circumferential direction of the stator core 21, and has a tendency to become smaller as separating away from the center WC of the wedge 25 in the circumferential direction of the stator core 21.

Thus, in the second embodiment, the strain of the wedge 25 is computed focusing on a strain component of the wedge 25 in the circumferential direction of the stator core 21. The strain of the wedge 25 can be detected not only by using a digital image correlation method, but also by using a moire method, which is publicly known as one of full field measurement methods.

The wedge 25 has a plurality of straight lines that are parallel to the axial direction of the stator core 21 as a pattern. Thus, the strain of the wedge 25 in the circumferential direction of the stator core 21, in which a change in strain is larger, can be more precisely detected.

In the second embodiment, the stripe pattern 62 is formed on the exposed surface 25a of the wedge 25 through application. However, a lattice pattern may be formed through application in place of the stripe pattern 62. The lattice pattern enables more precise detection of strain of the wedge 25 also in the axial direction of the stator core 21.

### Third Embodiment

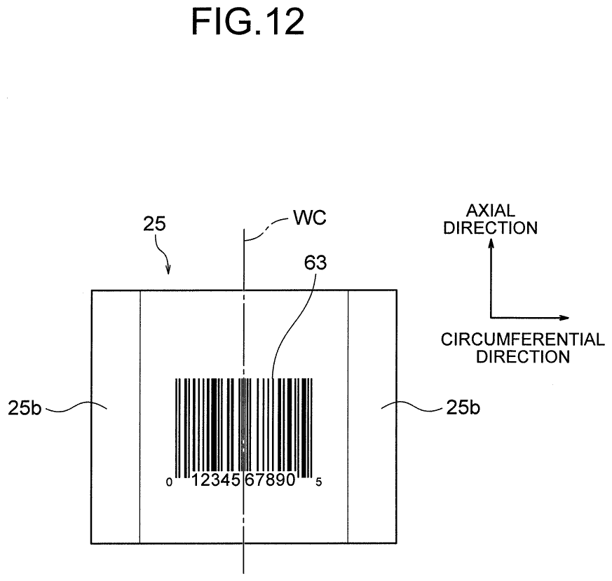

FIG. 12 is a plan view for illustrating a wedge 25 of a rotating electric machine according to a third embodiment. As illustrated in FIG. 12, an exposed surface 25a of the wedge 25 has a one-dimensional barcode 63, which is formed as a pattern through application.

Bars of the one-dimensional barcode 63 are formed on the exposed surface 25a of the wedge 25 through application so as to be parallel to an axial direction. The one-dimensional barcode 63 contains positional information of the wedge 25 with respect to a stator 20. The positional information is, for example, individual ID information or address information of the wedge 25.

A configuration of an inspection device 40 for a rotating electric machine 10, a configuration of the rotating electric machine 10, and a method of inspecting the rotating electric machine 10 are the same as those in the first embodiment except that a pattern is the one-dimensional barcode 63.

As described above, the one-dimensional barcode is formed on the wedge 25 as a pattern. Thus, the strain of the wedge 25 in a circumferential direction of a stator core 21 can be more precisely detected. Further, a position of the wedge 25 can easily be obtained by reading the one-dimensional barcode 63.

### Fourth Embodiment

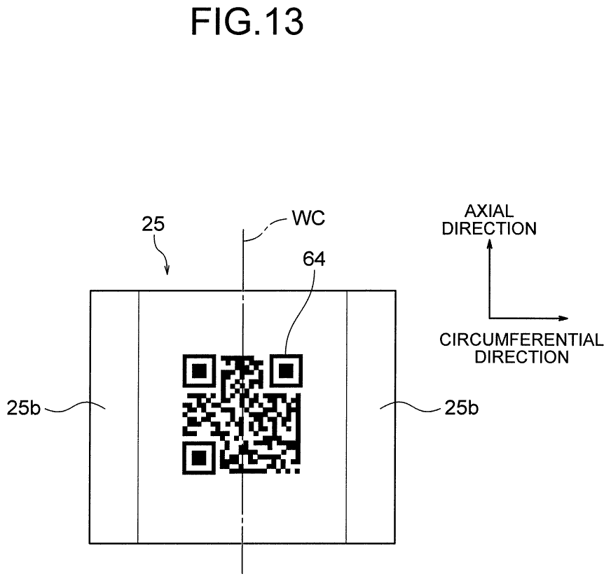

FIG. 13 is a plan view for illustrating a wedge 25 of a rotating electric machine according to a fourth embodiment. As illustrated in FIG. 13, an exposed surface 25a of the wedge 25 has a two-dimensional code 64, which is formed as a pattern through application.

The two-dimensional code 64 is formed on the exposed surface 25a of the wedge 25 through application so that sides of a plurality of squares included in the two-dimensional code 64 become parallel to an axial direction of a stator core 21 or a circumferential direction of the stator core 21.

The two-dimensional code 64 contains positional information of the wedge 25 with respect to a stator 20. The positional information is, for example, individual ID information or address information of the wedge 25. Further, the two-dimensional code 64 contains management information of the wedge 25. The management information includes, for example, a serial number and a date of manufacture of the wedge 25, a date of mounting of the wedge 25 into the stator 20, and a replacement history of the wedge 25.

A configuration of an inspection device 40 for a rotating electric machine 10, a configuration of the rotating electric machine 10, and a method of inspecting the rotating electric machine 10 are the same as those in the first embodiment except that a pattern is the two-dimensional code 64.

As described above, the wedge 25 has the two-dimensional code 64 as a pattern. Thus, strain of the wedge 25 in the circumferential direction of the stator core 21 and the axial direction of the stator core 21 can be precisely detected. Further, not only the positional information of the wedge 25 but also the management information of the wedge 25 can easily be obtained by reading the two-dimensional code 64.

The two-dimensional code 64 illustrated in FIG. 13 is a QR code (trademark). However, other matrix-type two-dimensional codes or stack-type two-dimensional codes may be used.

### Fifth Embodiment

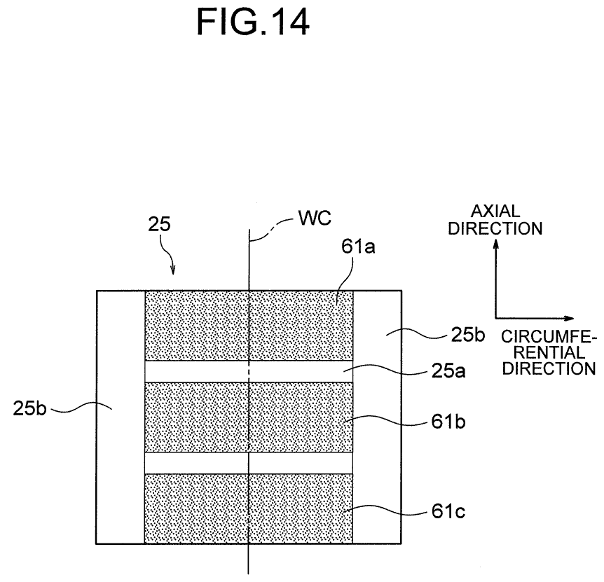

FIG. 14 is a plan view for illustrating a wedge 25 of a rotating electric machine according to a fifth embodiment. As illustrated in FIG. 14, an exposed surface 25a of the wedge 25 has three random patterns 61a, 61b, and 61c formed through application.

The random patterns 61a, 61b, and 61c are formed through application on the exposed surface 25a of the wedge 25 over a full length in a circumferential direction of a stator core 21. Further, the random patterns 61a and 61b are formed through application so as to be spaced apart from each other in an axial direction of the stator core 21, and the random patterns 61b and 61c are formed through application so as to be spaced apart from each other in the axial direction of the stator core 21.

As described above, strain of the wedge 25 in the circumferential direction of the stator core 21 has a tendency to become larger toward a center WC of the wedge 25. Also when the random pattern 61 is divided into a plurality of sections in the axial direction of the stator core 21, the above-mentioned tendency can be satisfactorily confirmed. Thus, loosening estimation accuracy can be sufficiently ensured.

As described in the first embodiment, the photographing control unit 51 moves the first photographing device 41a or the second photographing device 41b above the exposed surfaces 25a of the wedges 25, and photographs each random pattern 61 after dividing the random pattern 61 into a plurality of regions. Specifically, the number of pieces of image data to be inspected by an inspection device 40 depends on an area of the random pattern 61. Thus, time needed for the inspection device 40 to inspect one wedge becomes longer as the area of the random pattern 61 formed on the wedge becomes larger.

A sum of the areas of the random patterns 61a, 61b, and 61c in the fifth embodiment is smaller than an area of the random pattern 61 in the first embodiment. Thus, an inspection time period in the fifth embodiment is shorter than an inspection time period in the first embodiment.

A configuration of the inspection device 40 for a rotating electric machine 10, a configuration of the rotating electric machine 10, and a method of inspecting the rotating electric machine 10 are the same as those in the first embodiment except that the plurality of random patterns 61a, 61b, and 61c are formed so as to be separate from each other in the axial direction of the stator core 21.

Thus, the inspection time period can be further shortened while loosening estimation accuracy is ensured.

### Sixth Embodiment

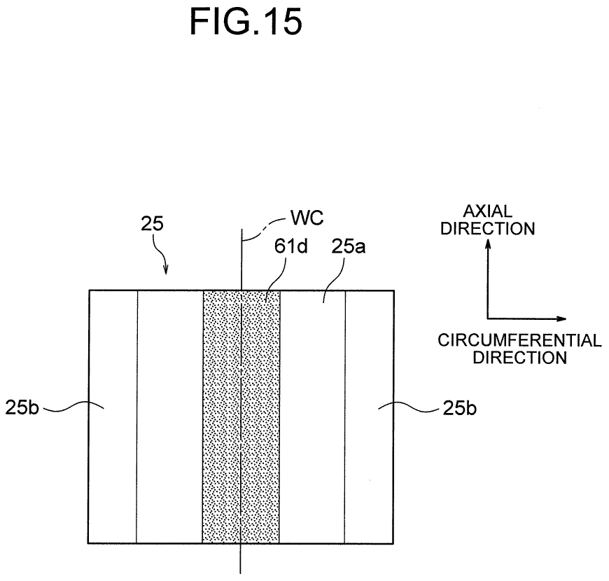

FIG. 15 is a plan view for illustrating a wedge 25 of a rotating electric machine according to a sixth embodiment. As illustrated in FIG. 15, an exposed surface 25a of the wedge 25 has a random pattern 61d formed through application.

As described above, a central portion of the wedge 25 in a circumferential direction of a stator core 21 is expected to have the largest strain of the wedge 25 in the circumferential direction of the stator core 21. Thus, an inspection device 40 according to the sixth embodiment measures strain based on image data of the central portion of the wedge 25, which is expected to have the largest strain in the circumferential direction.

A photographing control unit 51 photographs only a portion on which the random pattern 61d is formed through application. Thus, an inspection time period in the sixth embodiment becomes shorter than the inspection time period in the first embodiment.

A configuration of the inspection device 40 for a rotating electric machine 10, a configuration of the rotating electric machine 10, and a method of inspecting the rotating electric machine 10 are the same as those in the first embodiment except that the random pattern 61d is formed at least on the central portion of the wedge 25 in the circumferential direction of the stator core 21.

Thus, the inspection time period can be further shortened while loosening estimation accuracy is ensured.

### Seventh Embodiment

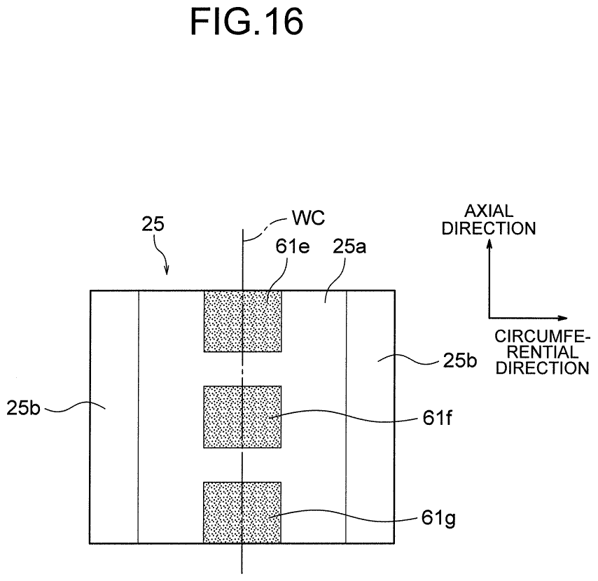

FIG. 16 is a plan view for illustrating a wedge 25 of a rotating electric machine according to a seventh embodiment. As illustrated in FIG. 16, an exposed surface 25a of the wedge 25 has random patterns 61e, 61f, and 61g formed through application.

More specifically, the random patterns 61e, 61f, and 61g are formed through application in a central portion including a center WC of the wedge 25. Further, the random patterns 61e and 61f are formed through application so as to be spaced apart from each other in an axial direction of a stator core 21, and the random patterns 61f and 61g are formed through application so as to be spaced apart from each other in the axial direction of the stator core 21.

Specifically, in the seventh embodiment, partial regions of the wedge 25, which include the center WC of the wedge 25 at which the strain of the wedge 25 in the circumferential direction of the stator core 21 is expected to be the largest, and which also extend in the axial direction of the stator core 21, are targets to be inspected.

A configuration of an inspection device 40 for a rotating electric machine 10, a configuration of the rotating electric machine 10, and a method of inspecting the rotating electric machine 10 are the same as those in the first embodiment except that the plurality of random patterns 61e, 61f, and 61g are arranged at least in the central portion of the wedge 25 in the circumferential direction of the stator core 21 so as to be separate from each other in the axial direction of the stator core 21.

The above-mentioned configurations and method enable detection of strain of the wedge 25 at least in the central portion of the wedge 25 in the circumferential direction of the stator core 21 and in a part extending in the axial direction of the stator core 21. Thus, an inspection time period can be further shortened while loosening estimation accuracy is ensured.

### Eighth Embodiment

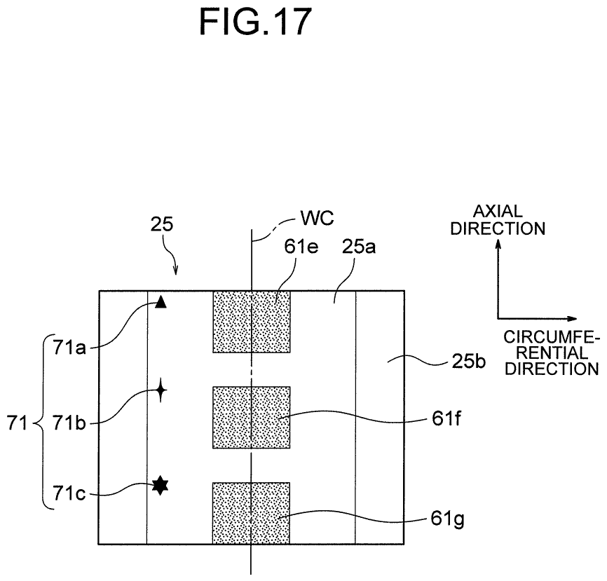

FIG. 17 is a plan view for illustrating a wedge 25 of a rotating electric machine according to an eighth embodiment. As illustrated in FIG. 17, an exposed surface 25a of the wedge 25 has random patterns 61e, 61f, and 61g formed through application.

Similarly to the random patterns in the seventh embodiment, the random patterns 61e, 61f, and 61g are formed through application in a central portion including a center WC of the wedge 25. The random patterns 61e and 61f are formed through application so as to be spaced apart from each other in an axial direction of a stator core 21, and the random patterns 61f and 61g are formed through application so as to be spaced apart from each other in the axial direction of the stator core 21.

Further, markers 71a, 71b, and 71c are formed through application on the exposed surface 25a of the wedge 25 in such a manner as to correspond to the random patterns 61e, 61f, and 61g, respectively. Those markers are collectively referred to as “markers 71.” The markers 71a, 71b, and 71c have shapes different from each other. The different shapes of the markers 71 enable the controller 50 to specify positions of the random patterns 61e, 61f, and 61g on the exposed surface 25a of the wedge 25.

The photographing control unit 51 photographs only a portion on which the random pattern 61e, 61f, or 61g is formed through application.

A configuration of an inspection device 40 for a rotating electric machine 10, a configuration of the rotating electric machine 10, and a method of inspecting the rotating electric machine 10 are the same as those in the first embodiment except that the markers 71a, 71b, and 71c for specifying the positions for photographing the random patterns 61e, 61f, and 61g are formed on the exposed surface 25a being part of a surface of the wedge 25.

Thus, the wedge 25, which is a target to be inspected, can easily be identified. As a result, an inspection time period can be further shortened.

In the eighth embodiment, the random pattern is formed as a pattern on the exposed surface 25a of the wedge 25 through application. However, a pattern to be combined with the markers 71 may be a kind of pattern different from the random pattern. Specifically, the markers 71 may be combined with a stripe pattern, a one-dimensional barcode, or a two-dimensional code.

### Ninth Embodiment

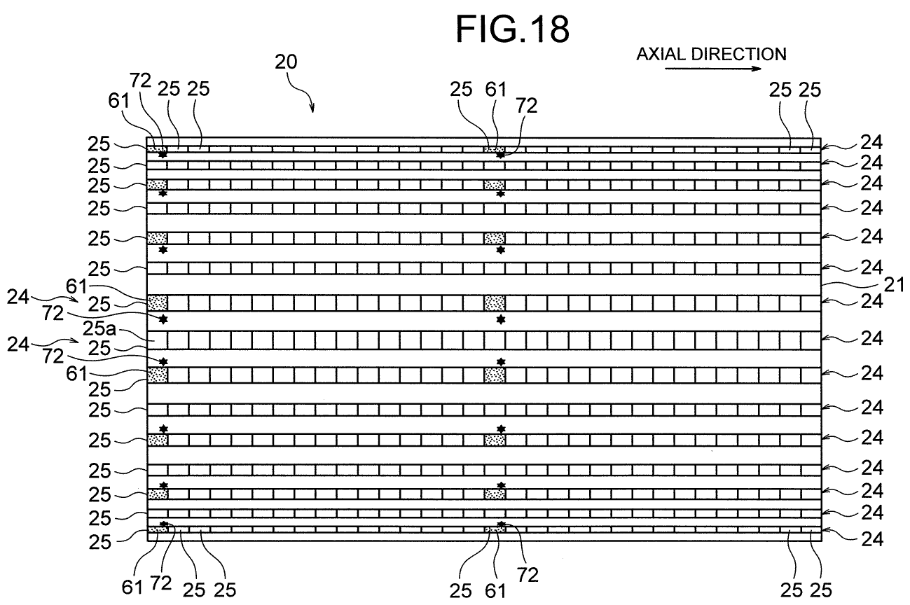

FIG. 18 is a view of part of an inner peripheral portion of a stator of a rotating electric machine according to a ninth embodiment when viewed from a rotor side. As illustrated in FIG. 18, wedges 25 without a random pattern 61 and wedges 25 with a random pattern 61 are mounted into stator core slots 24.

More specifically, the wedges 25 without the random pattern 61 and the wedges 25 with the random pattern 61 are mounted into one of two adjacent stator core slots 24. Only the wedges 25 without the random pattern 61 are mounted into the other one of the two adjacent stator core slots 24.

In the one stator core slot 24, one wedge 25 with the random pattern 61 is mounted on a left side in an axial direction a stator core 21, and one wedge 25 with the random pattern 61 is mounted at a center in the axial direction of the stator core 21. Further, markers 72 are formed on the stator core 21 in such a manner as to correspond to the wedges 25 with the random pattern 61.

A configuration of an inspection device 40 for a rotating electric machine 10, a configuration of the rotating electric machine 10, and a method of inspecting the rotating electric machine 10 are the same as those in the first embodiment except that the markers 72 for specifying positions for photographing the random patterns 61 are formed on a region of the stator 20 excluding the wedges 25. The region of the stator 20 excluding the wedges 25 is, for example, an inner peripheral surface of the stator core 21.

Thus, the wedge, which is a target to be inspected, can easily be identified. As a result, an inspection time period can be further shortened.

In the ninth embodiment, the arrangement of the wedges 25 with the random pattern 61 is a mere example, and is not limited to the arrangement illustrated in FIG. 18.

In the ninth embodiment, the random pattern is formed as a pattern on the exposed surface 25a of the wedge 25 through application. However, a pattern to be combined with the markers 72 may be a kind of pattern different from the random pattern. Specifically, the markers 72 may be combined with a stripe pattern, a one-dimensional barcode, or a two-dimensional code.

### Tenth Embodiment

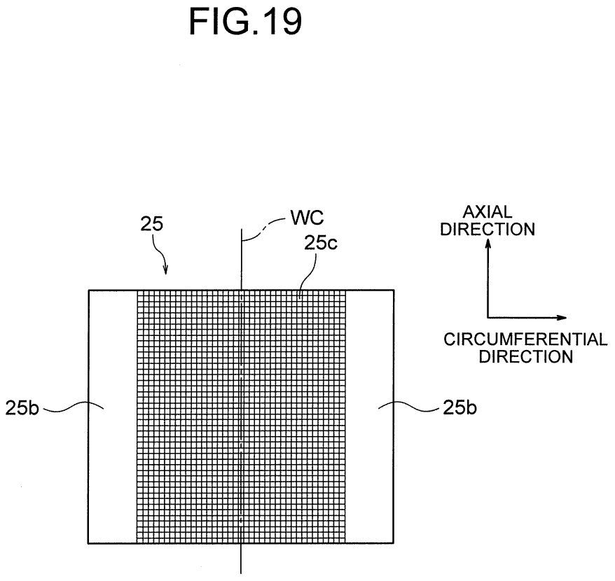

FIG. 19 is a plan view of a wedge 25 of a rotating electric machine according to a tenth embodiment. As illustrated in FIG. 19, the wedge 25 is formed by using fiber reinforced plastic containing a textile material of glass fiber as a base material. As a result, an exposed surface of the wedge 25 has a mesh-like lattice pattern 25c. In this case, strain is easily detected by using a commonly known moire method.

The use of the above-mentioned material eliminates a step of forming a pattern on the exposed surface of the wedge 25. Further, the pattern is less likely to degrade due to, for example, discoloration or peel-off in comparison to a case in which a pattern is formed on the exposed surface of the wedge 25. Thus, the stable detection of strain over a long period of time is enabled.

A marker 71 may be formed on the exposed surface of the wedge 25 in the tenth embodiment. The wedge 25 in the tenth embodiment may be mounted in the stator 20 with markers 72 formed on a region excluding the wedges 25.

### Eleventh Embodiment

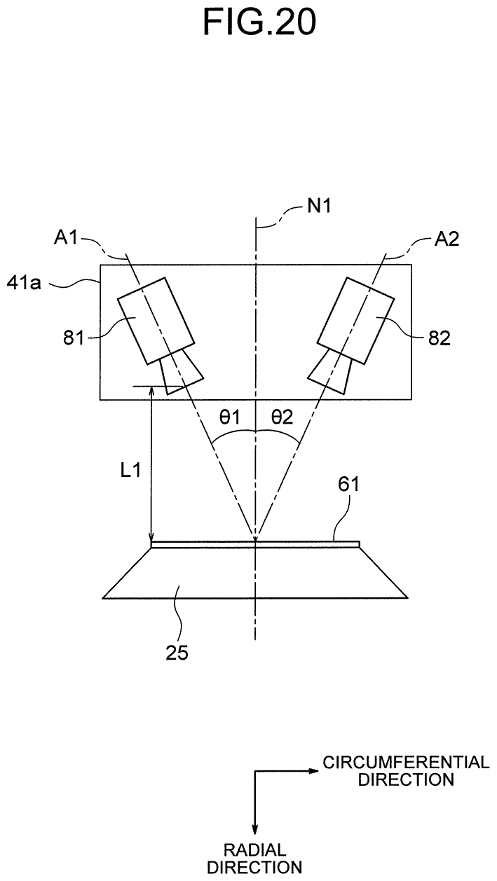

FIG. 20 is a view for illustrating a positional relationship between an inspection device for a rotating electric machine according to an eleventh embodiment and a wedge. As illustrated in FIG. 20, an exposed surface of a wedge 25 has a random pattern 61 formed through application. Further, only a first photographing device 41a is illustrated in FIG. 20 although the inspection device includes the first photographing device 41a and a second photographing device 41b.

The first photographing device 41a includes a first camera 81 and a second camera 82. The first camera 81 and the second camera 82 are mounted to the first photographing device 41a so that an angle θ1 and an angle θ2 become equal to each other. The angle θ1 is formed between an optical axis A1 of the first camera 81 and a normal N1 to a photographed region of the exposed surface of the wedge 25. The angle θ2 is formed between an optical axis A2 of the second camera 82 and the normal N1.

A configuration of an inspection device 40 for a rotating electric machine 10, a configuration of the rotating electric machine 10, and a method of inspecting the rotating electric machine 10 are the same as those in the first embodiment except that each of the first photographing device 41a and the second photographing device 41b includes a plurality of cameras for photographing the random pattern 61 in different directions.

A distance L1 between each of the first camera 81 and the second camera 82 and the random pattern 61 may change at each inspection time due to a mechanical error of the first drive mechanism 42a.

However, the inspection device for a rotating electric machine according to the eleventh embodiment can detect the distance L1 from image data photographed by the first camera 81 and the second camera 82. Thus, even when the distance L1 at a first inspection time and the distance L1 at a second inspection time are different from each other, a difference between those two distances can be corrected to enable precise detection of strain of the wedge 25.

In the eleventh embodiment, the random pattern 61 is formed on the exposed surface of the wedge 25. However, a kind of pattern, which is different from the random pattern, may be formed on the exposed surface of the wedge 25. A stripe pattern, a one-dimensional barcode, a two-dimensional code, or a mesh-like lattice pattern may be formed on the exposed surface of the wedge 25.

In the eighth and ninth embodiments, the marker is a mere geometric figure. However, the marker may be a one-dimensional barcode or a two-dimensional code. In this case, the marker contains recorded information such as a position, date of formation, date of inspection, or date of replacement of the wedge 25 being a target to be inspected.

In the first embodiment, all the wedges 25 have the random pattern 61 formed through application. Further, in the ninth embodiment, only predetermined two wedges among wedges mounted in two adjacent stator core slots 24 have the random pattern 61 formed through application.

However, the random pattern 61 may be formed through application only on a wedge that is to replace a wedge in the state in which the degree of loosening exceeds a specified value through an operation of the rotating electric machine 10. In this manner, only a wedge at a position that is expected to likely loosen is a target to be inspected. Thus, an inspection time period can be shortened.

In the first to ninth embodiment and the eleventh embodiment, the pattern is formed through application. However, the pattern may be formed by mechanical processing such as cutting or polishing. For example, the random pattern may be formed by sandblasting the exposed surface 25a of the wedge 25.

When the mechanical processing is used to form the pattern, for example, discoloration or a change in shape of the pattern is less likely to occur. Thus, an influence of a change in pattern with elapse of time on a result of detection of strain can be reduced. Further, the markers may also be formed by mechanical processing such as cutting or polishing.

Further, in the first to ninth embodiments and the eleventh embodiment, the pattern and the markers 71 may be printed on a sheet, and the sheet may be bonded to the exposed surface 25a of the wedge 25. Still further, the markers 72 may be printed on a sheet, and the sheet may be bonded onto a region of the stator 20 excluding the wedges 25.

In the inspection devices for a rotating electric machine according to the first to eleventh embodiments, the image data is stored in the image data storage unit 53. However, the image data may be stored in a storage device that is additionally provided outside the inspection device 40.

A method of detecting the strain of the wedge 25 is not limited to those described above. For example, the reference data may be data of a pattern of the wedge 25 when the pattern of the wedge 25 is photographed for the first time. The strain of the wedge 25 may be detected based on image data of the pattern obtained when the pattern of the wedge 25 is photographed for the first time and image data of the pattern photographed at a current inspection time.

Still further, when the pattern is, for example, a one-dimensional barcode, a two-dimensional code, or a printed random pattern, the reference data may be original data of a pattern, which is created in advance and stored in a storage device.

In the first to eleventh embodiments, a predetermined time period is a fixed time period. However, the predetermined time period may be set so as to be gradually shorter as elapsed time becomes longer. Further, the predetermined time period may be determined based not merely on elapsed time but also on actual operating time of the rotating electric machine 10.

Still further, a speed at which loosening of the wedge 25 progresses differs depending on a temperature and a humidity inside the frame 11. Thus, the predetermined time period may be determined in view of the temperature or the humidity inside the frame 11. Still further, the temperature inside the frame 11 has a correlation with an output from the rotating electric machine 10. Thus, the predetermined time period may be determined in view of the output from the rotating electric machine 10.

Further, the wedges 25 having a plurality of kinds of patterns may be used in one stator.

Further, one stator may have markers formed on the exposed surfaces of the wedges and markers formed on a region of the stator excluding the wedges.

In the first to ninth embodiments and the eleventh embodiment, fiber reinforced plastic is used as a material of the wedges 25. However, other resin materials having an insulating property may be used.

Each of the inspection devices for a rotating electric machine according to the first to eleventh embodiments includes two photographing devices and two drive mechanisms. However, only one photographing device and one drive mechanism may be provided on one of the right side or the left side in the axial direction of the stator core 21. Further, a plurality of photographing devices and a plurality of drive mechanisms may be provided on each of the right side and the left side.

Each of the inspection devices for a rotating electric machine according to the first to eleventh embodiments is used for a rotating electric machine including a stator in which wedges are mounted. However, the inspection device may be used for a rotating electric machine including a rotor in which wedges are mounted.

Each of the inspection devices for a rotating electric machine according to the first to eleventh embodiments is used for a rotating electric machine including a stator functioning as an armature and a rotor functioning as a field system. However, the inspection device may be used for a rotating electric machine including a stator functioning as a field system and a rotor functioning as an armature.

Each of the rotating electric machines according to the first to eleventh embodiments is a turbine generator. However, the rotating electric machine may be an electric motor.

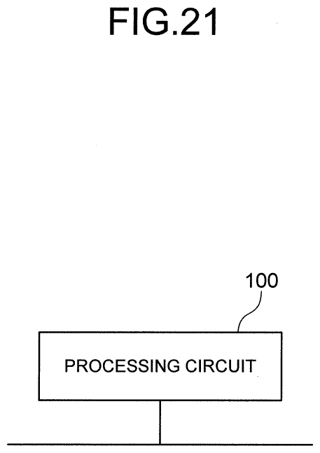

Further, each of the functions of the inspection devices for a rotating electric machine according to the first to eleventh embodiments is implemented by a processing circuit. FIG. 21 is a configuration diagram for illustrating a first example of the processing circuit for implementing each of the functions of the inspection devices for a rotating electric machine according to the first to eleventh embodiments. A processing circuit 100 of the first example is dedicated hardware.

Further, the processing circuit 100 corresponds to, for example, a single circuit, a complex circuit, a programmed processor, a processor for a parallel program, an application specific integrated circuit (ASIC), a field programmable gate array (FPGA), or a combination thereof. Further, the respective functions of the vehicle rear-lateral side monitoring apparatus may be implemented by individual processing circuits 100, or the functions may be collectively implemented by the processing circuit 100.

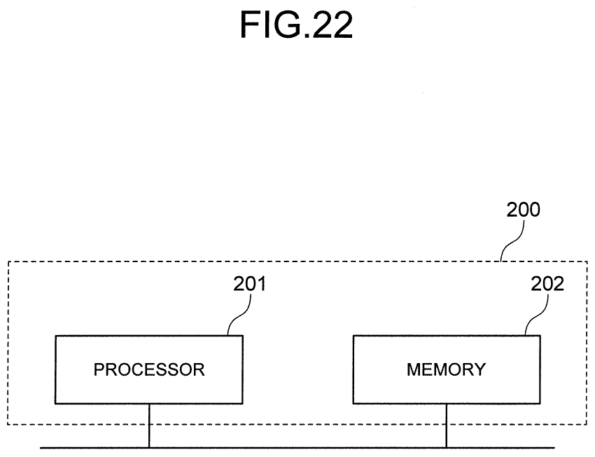

Further, FIG. 22 is a configuration diagram for illustrating a second example of the processing circuit for implementing each of the functions of the inspection devices for a rotating electric machine according to the first to eleventh embodiments. A processing circuit 200 of the second example includes a processor 201 and a memory 202.

In the processing circuit 200, the functions of the inspection devices for a rotating electric machine are implemented by software, firmware, or a combination of software and firmware. The software and the firmware are described as programs to be stored in the memory 202. The processor 201 reads out and executes the programs stored in the memory 202, to thereby implement the respective functions.

The programs stored in the memory 202 can also be regarded as programs for causing a computer to execute the procedure or method of each of the above-mentioned units. In this case, the memory 202 corresponds to, for example, a nonvolatile or volatile semiconductor memory, such as a random access memory (RAM), a read only memory (ROM), a flash memory, an erasable programmable read only memory (EPROM), or an electrically erasable and programmable read only memory (EEPROM). Further, a magnetic disk, a flexible disk, an optical disc, a compact disc, a mini disc, or a DVD may also correspond to the memory 202.

The function of each of the above-mentioned units may be implemented partially by dedicated hardware, and partially by software or firmware.

In this way, the processing circuit can implement the function of each of the above-mentioned units by hardware, software, firmware, or a combination thereof.

### REFERENCE SIGNS LIST

10 rotating electric machine, 13 gap, 20 stator (armature), 21 stator core, 22 stator winding, 24 stator core slot, 25 wedge, 25a exposed surface (surface), 26 spring, 30 rotor, 32 rotor core, 40 inspection device, 41a first photographing device, 41b second photographing device, 42a first drive mechanism, 42b second drive mechanism, 50 controller, 61 random pattern (pattern), 62 stripe pattern (plurality of straight lines), 63 one-dimensional barcode, 64 two-dimensional code, 71, 71a, 71b, 71c, 72 marker, 81 first camera, 82 second camera, WC center of wedge

1-18. (canceled)

19. An inspection device for a rotating electric machine, comprising:
a photographing device configured to photograph a pattern formed on a surface of a wedge constituting part of an armature; and
a controller configured to:
generate temporal change information of in-plane strain distribution of the wedge by comparing image data of the pattern photographed by the photographing device with image data of the pattern previously photographed at the same position through use of a digital image correlation method in which an amount of displacement and a direction of displacement of a surface of a target object are simultaneously calculated from a luminance distribution of the image data; and
estimate loosening of the wedge based on the generated temporal change information of the in-plane strain distribution, and on a relationship between the temporal change information of the in-plane strain distribution and a degree of loosening of the wedge, which is stored in advance.

20. The inspection device for a rotating electric machine according to claim 19, wherein markers for specifying positions for photographing the patterns are formed on the portions on which random patterns are not formed among the surface of the wedge.

21. The inspection device for a rotating electric machine according to claim 19, wherein markers are formed on the armature.

22. The inspection device for a rotating electric machine according to claim 19, further comprising a drive mechanism configured to move the photographing device with respect to the armature,
wherein the controller is configured to control the drive mechanism.

23. The inspection device for a rotating electric machine according to claim 19, wherein the photographing device includes a plurality of cameras configured to photograph the pattern in different directions.

24. A rotating electric machine, comprising the inspection device of claim 19.

25. The rotating electric machine according to claim 24, wherein the wedge has a random pattern as the pattern.

26. The rotating electric machine according to claim 24, wherein the wedge has a plurality of straight lines being parallel to an axial direction of the armature as the pattern.

27. The rotating electric machine according to claim 24, wherein the wedge has a one-dimensional barcode as the pattern.

28. The rotating electric machine according to claim 24, wherein the wedge has a two-dimensional code as the pattern.

29. The rotating electric machine according to claim 27, wherein the pattern contains positional information of the wedge.

30. The rotating electric machine according to claim 28, wherein the pattern contains positional information of the wedge.

31. The rotating electric machine according to claim 24, wherein the pattern is formed at least on a central portion of the wedge in a circumferential direction of the armature.

32. The rotating electric machine according to claim 31, wherein the pattern is formed so as to be divided into a plurality of sections in the axial direction of the armature.

33. The rotating electric machine according to claim 24, wherein markers are formed on the armature.

34. The rotating electric machine according to claim 33, wherein markers for specifying positions for photographing the patterns are formed on the portions on which random patterns are not formed among the surface of the wedge.

35. An inspection device for a rotating electric machine, comprising a controller configured to:
generate temporal change information of in-plane strain distribution of a wedge constituting part of an armature by comparing image data of a pattern formed on a surface of the wedge, which has been acquired by a photographing device configured to photograph the pattern, with image data of the pattern previously photographed at the same position through use of a digital image correlation method in which an amount of displacement and a direction of displacement of a surface of a target object are simultaneously calculated from a luminance distribution of the image data; and
estimate loosening of the wedge based on the generated temporal change information of the in-plane strain distribution, and on a relationship between the temporal change information of the in-plane strain distribution and a degree of loosening of the wedge, which is stored in advance.

36. A method of inspecting a rotating electric machine, the method comprising:
forming a pattern on a surface of a wedge constituting part of an armature;
photographing the pattern with a photographing device; and
generating temporal change information of in-plane strain distribution of the wedge by comparing image data of the pattern photographed by the photographing device with image data of the pattern previously photographed at the same position through use of a digital image correlation method in which an amount of displacement and a direction of displacement of a surface of a target object are simultaneously calculated from a luminance distribution of the image data, and estimating loosening of the wedge based on the generated temporal change information of the in-plane strain distribution, and on a relationship between the temporal change information of the in-plane strain distribution and a degree of loosening of the wedge, which is stored in advance.

37. A method of inspecting a rotating electric machine, the method comprising:
mounting a wedge having a surface with a pattern into an armature;
photographing the pattern with a photographing device; and
generating temporal change information of in-plane strain distribution of the wedge by comparing image data of the pattern photographed by the photographing device with image data of the pattern previously photographed at the same position through use of a digital image correlation method in which an amount of displacement and a direction of displacement of a surface of a target object are simultaneously calculated from a luminance distribution of the image data, and estimating loosening of the wedge based on the generated temporal change information of the in-plane strain distribution, and on a relationship between the temporal change information of the in-plane strain distribution and a degree of loosening of the wedge, which is stored in advance.
